(19) United States
(12) Patent Application Publication
(10) Pub. No.: US 2007/0220402 A1
(43) Pub. Date: Sep. 20, 2007

(54) Auxiliary storage device and read/write method

(75) Inventors: Eiji Hagi, Kanagawa-ken (JP); Takeshi Shikama, Kanagawa (JP); Takayuki Umemoto, Kanagawa (JP); Akira Kojima, Kanagawa (JP)

Correspondence Address: TOWNSEND AND TOWNSEND AND CREW LLP, TWO EMBARCADERO CENTER, 8TH FLOOR, SAN FRANCISCO, CA, 94111, US

(73) Assignee: Hitachi Global Storage Technologies Netherlands B.V., Amsterdam (NL)

(21) Appl. No.: 11/652,388

(22) Filed: Jan. 10, 2007

(30) Foreign Application Priority Data
Jan. 10, 2006 (JP) 2006-002013

(51) Int. Cl. G11C 29/00

(52) U.S. Cl. 714/766

(57) ABSTRACT

Embodiments in accordance with the present invention provide an auxiliary storage device that prevents performance degradation and collects data useful for buffer failure analysis. In one embodiment, a data set including user data and cyclic redundancy check (CRC) information is temporarily stored in a buffer. If a CRC error is detected in a data set that is read from the buffer during a data write or data read, the contents of the data set and the affected buffer address are recorded on a nonvolatile recording medium. Further, the buffer address is disabled. This makes it possible to store the data for reproducing a soft error that occurs in the buffer and prevent the performance of the auxiliary storage device from being degraded by a buffer error.

### CROSS-REFERENCE TO RELATED APPLICATION

The instant nonprovisional patent application claims priority to Japanese Application No. 2006-002013, filed Jan. 10, 2006 and incorporated by reference herein for all purposes.

### BACKGROUND OF THE INVENTION

Embodiments in accordance with the present invention relate to a technology for using a buffer in an auxiliary storage device, and more particularly to a technology for improving a buffer use method, gathering data useful for failure analysis, and preventing performance degradation.

Most computer systems employ an auxiliary storage device, which provides virtually perpetual storage of data, in addition to a main storage device, which stores programs to be executed by a CPU and offers a work area. The auxiliary storage device may be referred to as a large-capacity storage device because it generally has a larger storage capacity than the main storage device. Further, it may also be referred to as an external storage device because it is an external storage separate from the main storage device, which is provided for the CPU. Typical auxiliary storage devices are, for instance, a magnetic disk drive, a floppy disk drive (the floppy disk is a trademark), a magnetooptical disk drive, a CD-RW drive, and a DVD-RW drive.

These auxiliary storage devices are connected to a computer system, which serves as a host device, through a SCSI, IDE, or other interface circuit, and are used to record data sent from the host device or send recorded data to the host device. The auxiliary storage devices include a buffer to absorb the time lag between data communication with the host device and an internal process for a read or write.

The magnetic disk drive, which is a typical auxiliary storage device, includes a sector buffer for temporarily storing data. The magnetic disk drive establishes data communication with the host device via the sector buffer to improve its performance. A semiconductor memory such as an SRAM or DRAM is used as the sector buffer. Although the semiconductor memory is a stable recording medium, an error is infrequently found in the data read from it. The magnetic disk drive adds an error checking code to the data by using a detection technology called a cyclic redundancy check (CRC), stores the data in the sector buffer, and checks for an error in the data when it is read.

When a read command or write command transmitted from the host device is to be processed, the error checking code is used to detect an error in the data read from the sector buffer. If an error is detected when the read command is processed, the data in error is read again from a magnetic disk through a read channel. If an error is detected when the write command is processed, write data is received again from the host device.

Patent Document 1 (Japanese Laid-Open Patent No. 196680/2005) discloses a technology that stores an error occurrence address and bit position in a nonvolatile memory when an error occurs in a memory used in a personal computer for the purpose of determining whether the error is a perpetual error (hard error) or temporary error (soft error). Patent Document 2 (Japanese Laid-Open Patent No. 78853/1998) discloses a magnetic disk drive that adds a CRC byte to data, stores the data in a buffer memory, and verifies an error contained in user data and CRC byte by using an ECC byte.

When an error is detected in the data stored in the sector buffer, the magnetic disk drive needs to perform a reprocessing operation for the purpose of storing data in the sector buffer. Since data is transferred again from the host device in a write operation and data is read again from the magnetic disk in a read operation, the performance of the magnetic disk drive degrades.

If a hardware failure occurs at a particular bit address of the sector buffer, a perpetual error occurs without regard to the value of a written data bit so that the value of read data is always 0 or 1, and an error occurs when an inverted bit value is output depending on the contents of data (this error is hereinafter referred to as a hard error). The hard error is such that when data 1 or data 0 is stored at the relevant bit address, an error always occurs in either case. Therefore, a faulty bit address can be examined to analyze the cause of a failure.

In recent years, the degree of integration of semiconductor memories has increased due to advances in miniaturization technology. However, the immunity from disturbances such as neutrons, alpha rays or other radiation, and magnetic noise has decreased. Therefore, a soft error in which the stored bit value becomes inverted tends to occur with a low probability. Thus, the longer the period of data storage in the sector buffer, the higher the probability of soft error occurrence. Further, the soft error may be affected by a data pattern (bit pattern). It may be impossible to thoroughly avoid the occurrence of soft error in the sector buffer. As regards the sector buffer in which a soft error frequently occurs, however, it is necessary to investigate the error cause and take an appropriate countermeasure. In reality, however, it is difficult to identify the error cause because the soft error cannot possibly be reproduced even when the sector buffer in soft error is analyzed.

Formerly, when an error was detected in the data read from the sector buffer, the magnetic disk drive merely informed the host device of an error occurrence and continuously used a sector buffer segment in which the error occurred (hereinafter referred to as an error segment) while it was permitted by the host device. If the error segment is continuously used so that an error is reported to the host device at predetermined intervals, the host device concludes that the magnetic disk drive is faulty. Before the host device concludes that the magnetic disk drive is faulty, the data is written again in the buffer so that the performance of the magnetic disk drive remains low. It is difficult to clearly distinguish between soft errors and hard errors. However, it is conceivable that frequent soft errors may be caused by a hard factor. The use of such an address or segment should be avoided to prevent performance degradation.

Formerly, the magnetic disk drive did not store error information even when an error was detected in the data read from the sector buffer. Since it was difficult to reproduce a soft error, it was practically impossible to obtain useful information for determining whether the soft error occurs at a particular address or at all addresses, judging whether the soft error relates to a data pattern, or investigating the cause of the soft error.

### BRIEF SUMMARY OF THE INVENTION

Embodiments in accordance with the present invention provide an auxiliary storage device that prevents performance degradation and collects data useful for buffer failure analysis. In accordance with one embodiment, a data set including user data and CRC information is temporarily stored in a buffer. If a CRC error is detected in a data set that is read from the buffer during a data write or data read, the contents of the data set and the affected buffer address are recorded on a nonvolatile recording medium. Further, the buffer address is disabled. This makes it possible to store the data for reproducing a soft error that occurs in the buffer and prevent the performance of the auxiliary storage device from being degraded by a buffer error.

### BRIEF DESCRIPTION OF THE DRAWINGS

FIG. 1 is a block diagram illustrating a magnetic disk drive according to an embodiment of the present invention.

FIGS. 2(a) and 2(b) show the format of a magnetic disk.

FIG. 3 is a flowchart illustrating a sector buffer management procedure that is performed during a write operation.

FIGS. 4(a) to 4(c) show the data structure of a sector buffer.

FIGS. 5(a) and 5(b) illustrate a method for identifying an error bit address of the sector buffer.

FIG. 6 is a flowchart illustrating a sector buffer management procedure that is performed during a read operation.

### DETAILED DESCRIPTION OF THE INVENTION

An object of embodiments in accordance with the present invention is to provide an auxiliary storage device that uses an improved buffer management method to prevent performance degradation. Another object of embodiments in accordance with the present invention is to provide an auxiliary storage device that is capable of gathering data useful for buffer failure analysis. Still another object of the present invention is to provide an auxiliary storage device's read/write method that prevents performance degradation.

One aspect of embodiments in accordance with the present invention provides an auxiliary storage device that gathers data useful for the failure analysis of a buffer. A data set is constituted by a user data block and an error checking code that is generated in accordance with the user data block, and stored on a nonvolatile recording medium. The data set is once stored in the buffer no matter whether a read or write operation is performed. When the data set is to be read, an error correction code is used to check for an error.

When an error is detected in a first data set read from the buffer, a processor records on the nonvolatile recording medium, the data set in which the error is detected and an address of the buffer at which the data set has been stored. As a result, the recording medium perpetually records a bit pattern of the data set in which the error occurred and the buffer address. Therefore, they can be used to conduct a buffer error reproduction test. The buffer address to be recorded on the recording medium may include a logical block address corresponding to the data set.

When the auxiliary storage device reports an error to a host device in the event of error detection during a write operation, the same user data is transferred from the host device. Alternatively, the auxiliary storage device may issue a data retransmission request to the host device. A second data set, which is obtained by adding an error checking code to retransmitted user data, is stored at an address other than a buffer address at which the data set in error has been stored (hereinafter referred to as the error address).

If a hard error or frequent soft error is generated at a particular address of the buffer and a data set is stored at the same address, the error recurs so that performance degrades. However, such performance degradation can be prevented by storing the data set at another address. The user data block includes a plurality of bits and the error checking code checks for an error on an individual data set basis. Therefore, an error bit cannot be identified simply by detecting an error in a data set.

If no error is detected in the second data set of the retransmitted user data block, embodiments of the present invention compares the first data set, in which an error has been detected, and the retransmitted second data set on a bit-by-bit basis to locate an error bit address at which the first data set has been stored, and records the error bit address on the nonvolatile recording medium. Consequently, a buffer error analysis can be made with the buffer error location identified on a bit-by-bit basis.

When data is to be transferred from the recording medium to the host device during a read operation, a data set that is read from the recording medium and composed of a user data block and error checking code is temporarily stored in the buffer, the data set is read from the buffer, and then user data is transferred to the host device. When the data set is to be read from the buffer, it is checked for an error in the same manner as for a write operation. If an error is detected, the buffer address at which the data set has been stored and the data set are recorded on the recording medium. When an error is detected, the same data set is read again from the recording medium. The read data set is stored at an address other than the buffer address at which the error occurred, and checked for an error.

The recording medium may be a hard disk, CD-RW disk, DVD-RW disk, DVD-RAM disk, MO disk, or other rotary disc type read/write recording medium. It may also be a flash memory or other read/write semiconductor memory. Information such as the error checking code generated by the cyclic redundancy check (CRC) method or checksum method may be used. Further, the error checking code may incorporate an error correction capability. Since the data and address information about an error is recorded in a system region that is allocated on the recoding medium by the auxiliary storage device, it will not be overwritten by user data.

Another aspect of embodiments in accordance with the present invention provides an auxiliary storage device that uses an improved buffer management method to prevent performance degradation. When an error is detected in a data set that is read from the buffer, the auxiliary storage device according to embodiments of the present invention disables the associated buffer address. This reduces the probability with which the error recurs due to the use of the same address. Further, it makes it possible to prevent performance degradation of the auxiliary storage device because it reduces the frequency with which the host device retransmits a user data block or the nonvolatile recording medium is read again.

When a buffer address is to be disabled, it can be disabled only when an error is detected in a data set stored at the same address a predetermined number of times. Errors detected in the buffer are mostly soft errors. If the address is disabled when a soft error occurs infrequently, the capacity of the buffer is unduly reduced. However, if the soft error is detected at the same address a predetermined number of times, the address can be disabled because it can be concluded that the soft error occurs frequently. Upon receipt of a report indicating the occurrence of an error at a particular buffer address from the auxiliary device, the host device can disable the address.

Advantages of the Invention

Embodiments in accordance with the present invention provide an auxiliary storage device that uses an improved buffer management method to prevent performance degradation. Further, embodiments of the present invention provide an auxiliary storage device that is capable of gathering data useful for buffer failure analysis. Furthermore, embodiments of the present invention provide an auxiliary storage device's read/write method that prevents performance degradation.

Device Configuration

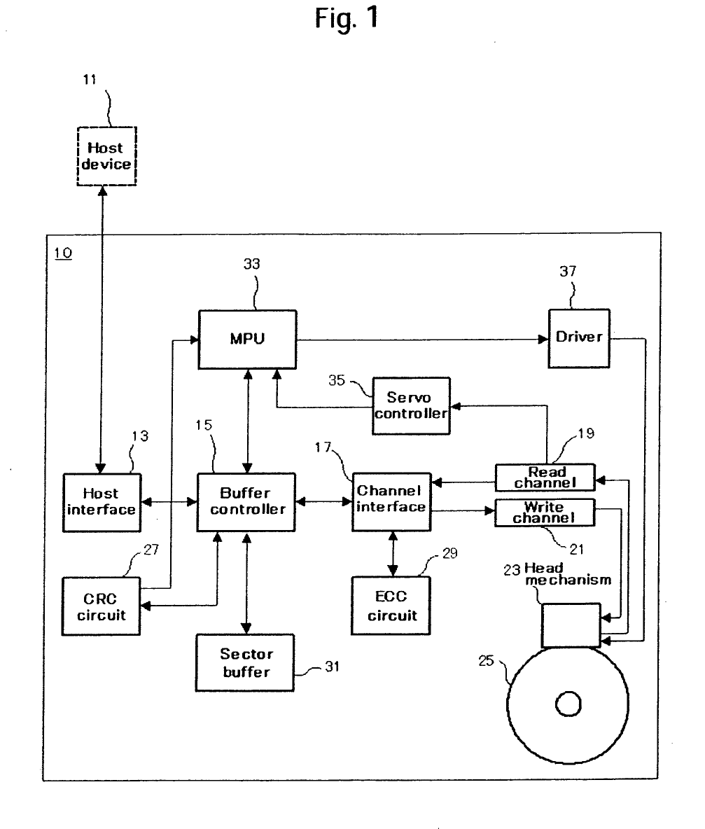

FIG. 1 is a schematic block diagram illustrating a magnetic disk drive 10 according to an embodiment of the present invention. The magnetic disk drive 10 is connected to a computer, music recorder/player, or other host device 11 and used to record data received from the host device 11 or send data recorded on a magnetic disk 25 to the host device 11. A host interface circuit 13 is an ATA circuit that provides control over data communication between the host device 11 and magnetic disk drive 10. Data, command, and control information input/output operations are performed between the host device 11 and magnetic disk drive 10 via the host interface circuit 13.

When the host device 11 is set to write data into the magnetic disk drive 10 or read data from the magnetic disk drive, it accesses an ATA register address that is allocated to the host interface circuit 13. ATA registers are a command register, a status register, a data register, a cylinder low/high register, a sector number register, a sector count register, and the like.

When the host device 11 transfers data in relation to the magnetic disk drive 10, it writes a read command or write command into the command register and the logical block address (hereinafter referred to as the LBA) of a leading data sector in the cylinder low/high register and sector number register. It transmits/receives data with the number of read/write data sectors specified in the sector count register. If an error occurs while the read command or write command is executed, the magnetic disk drive 10 sets a status register error bit to report the error to the host device 11.

A buffer controller 15 exercises control over data input/output concerning a sector buffer 31 and a CRC circuit 27. The sector buffer 31 is an SDRAM. Its capacity is 8 MB in the present embodiment. The sector buffer 31 is used to exercise a read cache function and write cache function in order to absorb the difference between the processing speed prevailing inside the magnetic disk drive 10 and the speed of transfer relative to the host device 11 for performance improvement. The sector buffer 31 is divided into segments of the same size to raise the cache hit rate and simultaneously exercise the read cache and write cache functions. In the present embodiment, the sector buffer 31 is divided into 16 segments. It can be divided into up to 128 to 256 segments. The capacity of the sector buffer 31 and the number of its segments can be defined as desired.

For user data transmitted from the host interface circuit 13 to the buffer controller 15, the CRC circuit 27 calculates an error checking code (hereinafter referred to as the CRCC), which serves as a redundant byte, by using a generator polynomial based on the cyclic redundancy check (CRC) method, and sends the calculated CRCC to the buffer controller 15. In the present embodiment, the CRCC is calculated for each 512-byte user data, which is equivalent in size to a data sector, and composed of 4 bytes. The buffer controller 15 controls the sector buffer 31 in order to store a 516-byte data set, which contains 512 bytes of user data and 4 bytes of CRCC, at a predetermined address of the sector buffer 31.

Before a data transmission to the host device 11 and a data write onto the magnetic disk 25, the CRC circuit 27 uses a generator polynomial to check for a bit inversion error in a data set that is loaded from the sector buffer 31 to the buffer controller 15. The CRC circuit 27 informs an MPU 33 of an error detected in the data set (hereinafter referred to as the CRC error). In the present embodiment, the CRC circuit 27 merely checks for an error. However, it may additionally incorporate an error correction function.

A channel interface circuit 17 exercises control over data input/output operations relative to the buffer controller 15, read channel 19, write channel 21, and ECC circuit 29. The ECC circuit 29 calculates an error correction code (hereinafter referred to as the ECC) by the reed solomon method from a write-related data set that is transmitted from the buffer controller 15 to the channel interface circuit 17 during a write operation, and sends the calculated ECC to the channel interface circuit 17. Approximately 20 to 40 bytes of ECC are generated for each 516-byte data set.

The ECC circuit 29 calculates an error syndrome from the data set and ECC, which are transmitted from the read channel 19 to the channel interface circuit 17 during a read operation, and checks for a bit inversion error in the data set. If the number of bit inversion errors is not larger than a predetermined number, the ECC circuit 29 corrects the data set and transmits the corrected data set to the buffer controller 15.

The read channel 19 processes the user data read from the magnetic disk 25 and transmits it to the channel interface circuit 17. The read channel 19 processes servo data read from the magnetic disk 25 and forwards it to a servo controller 35. The write channel 21 processes write-related data sector information, which is received from the channel interface circuit 17, and transmits the processed data sector information to a head mechanism 23. The data sector information includes a preamble, postamble, address information, and other information generated and added by a known method in addition to the data set and ECC.

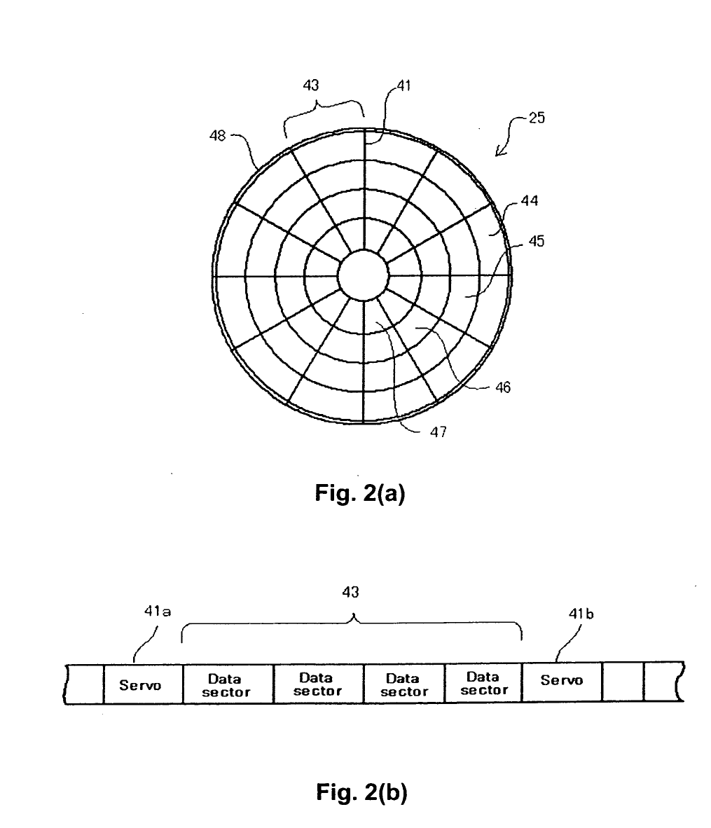

The head mechanism 23 includes a magnetic head and a carriage mechanism that places the magnetic head at a specific position of the magnetic disk 23. FIGS. 2(A) and 2(B) show a format of the magnetic disk 25. The magnetic disk 25 is in a format that is applied to a magnetic disk drive based on a data plane servo scheme. As shown in FIG. 2(A), a plurality of radially extended servo sectors 41 are written on the magnetic disk 25. As shown in FIG. 2(B), a data region 43 is positioned between the servo sectors 41 a and 41 b, and a plurality of data sectors are defined in the data region 43. Basically the same positional relationship exists between the other servo sectors and data regions.

The magnetic disk drive 10 employs a zone bit recording method, and zones 44, 45, 46, and 47 are defined in radial direction. A system region 48 is defined in the vicinity of the outermost track of zone 44. The magnetic disk drive 10 uses the system region 48 exclusively and does not allow the user to access it. In order from the outermost track to the innermost track, LBAs are sequentially assigned to all data sectors of the magnetic disk 25.

Returning to FIG. 1, the MPU 33 includes a processor, a RAM, an EEPROM, and a firmware storage ROM, and controls the entire operation of the magnetic disk drive 10. The MPU 33 interprets a command that the host device 11 writes in an ATA register of the host interface circuit 13, and controls the operation of the magnetic disk drive 10 accordingly. If an error occurs when a command transmitted from the host device 11 is to be executed, the MPU 33 sets an error bit in the status register of the host interface circuit 13 to report the error to the host device 11. The MPU 33 also manages the addresses of the sector buffer 31 and implements the cache functions.

The servo controller 35 receives servo information from the read channel 19, processes the received servo information, and sends magnetic head position information to the MPU 33. The MPU 33 generates control information for the head mechanism 23 in accordance with the position information transmitted from the servo controller 35, and transmits the generated control information to a driver 37. The driver 37 generates a control current for placing the head mechanism 23 at a position specified by the MPU 33, and transmits the generated control current to the head mechanism 23. Many other known elements are required to construct the magnetic disk drive 10. However, they are not described here because they are not particularly relevant to certain embodiments of the present invention. The functional block shown in FIG. 1 is prepared as an example. A person of ordinary skill in the art would understand that some of the functions described with reference to FIG. 1 can be incorporated into a single semiconductor device or further divided.

Process for a Data Write

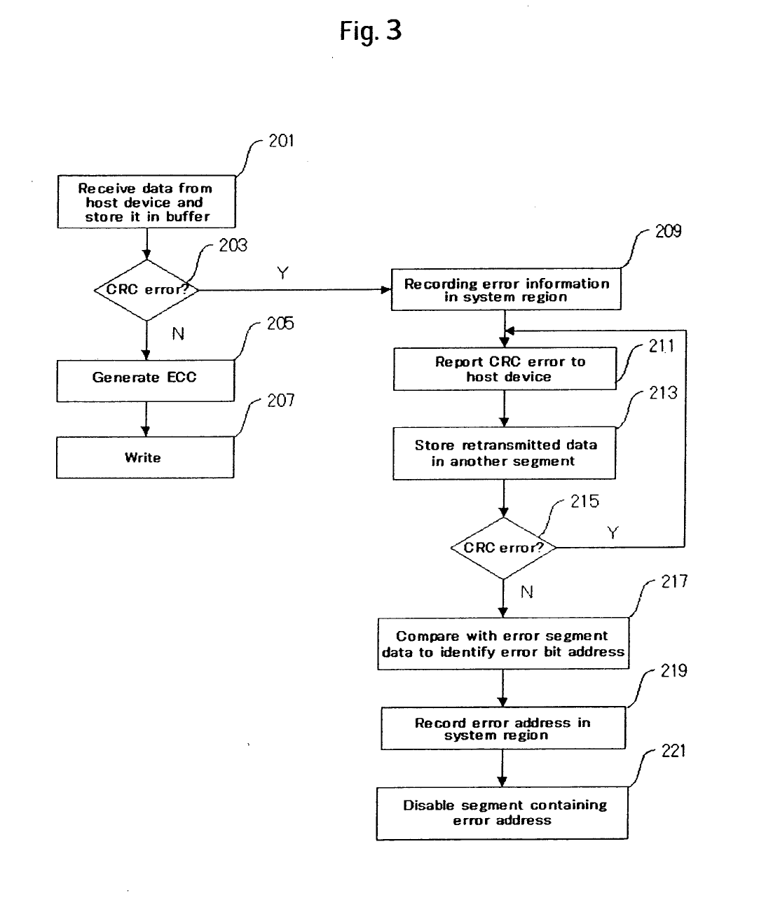

FIG. 3 is a flowchart illustrating a sector buffer management procedure according to an embodiment of the present embodiment that is employed when the host device 11 writes data on the magnetic disk 25. The sector buffer management procedures for a read operation and write operation are incorporated in the firmware of the MPU 33. In step 201, write-related user data is transferred from the host device 11 to the magnetic disk drive 10 and stored in the sector buffer 31. The host device 11 specifies the LBA of the leading data sector on the magnetic disk and the number of data sectors to be written, and sends a write command and user data to an ATA register of the host interface circuit 13. The user data to be transferred is made of 512-byte data blocks as is the case with the data sectors stored on the magnetic disk 25. One write command transfers a group of a plurality of data blocks.

The MPU 33 interprets the write command, determines, in accordance with an LRU (Least Recently Used) algorithm, the segment of the sector buffer 33 that stores the data block group, and controls the buffer controller 15. The buffer controller 15 receives the data block group from the host interface circuit 13. The CRC circuit 27 calculates the CRCC for each data block in the data block group and sends the calculation results to the buffer controller 15. From the data blocks received from the host interface circuit 13 and their CRCCs, the buffer controller 15 formulates a data set for each data block in the data block group, and stores the resulting data set group in the segment specified by the MPU 33.

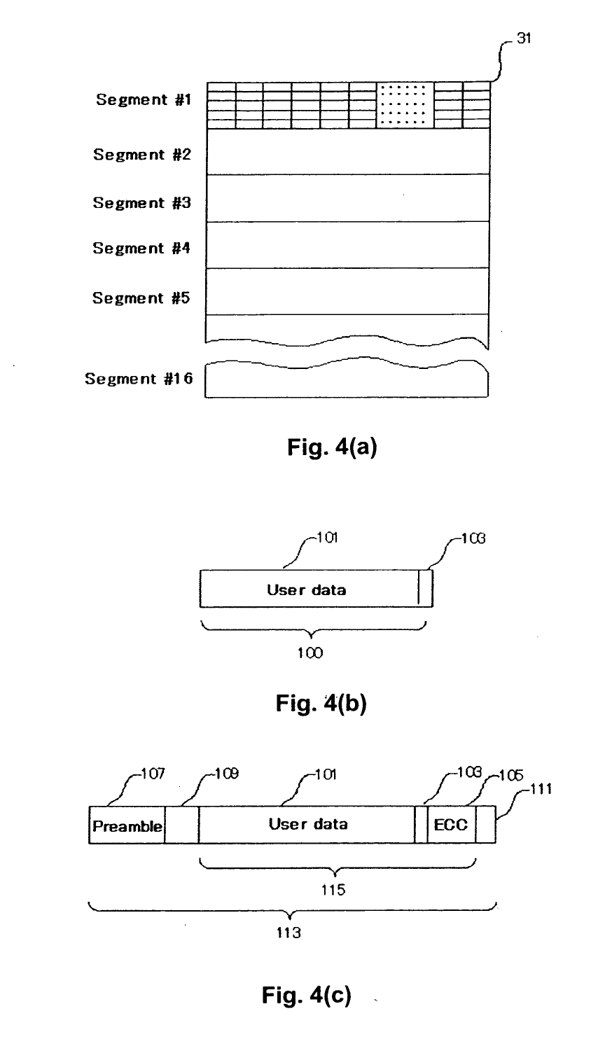

FIG. 4(A) shows the data structure of the sector buffer 31. The sector buffer 31 is divided into 16 segments (segments #1 to #16). All the segments have the same structure so that each segment can store 800 data sets 100 in LBA order. The present embodiment stores the data set group in segment #1. FIG. 4(B) shows the data structure of a data set 100. The data set 100 includes 512-byte user data (data block) and 4-byte CRCC. It has a fixed block length of 516 bytes. The MPU 33 stores in the EEPROM the segment number (#1) and the LBA for the leading data set. In accordance with the LBA for the leading data set stored in each segment and the position of a data set in which a CRC error has been detected in relation to the leading data set, the MPU 33 can calculate the LBA of the data set in which the CRC error has been detected and the buffer address at which the data set has been stored.

In the next step (step 203), the buffer controller 15 sequentially reads a group of data sets from segment #1 of the sector buffer 31 with such timing that data can be sent to the channel interface circuit 17. In this instance, the CRC circuit 27 checks for a CRC error in each data set. If the CRC error is not detected in any data set in the data set group stored in a data segment, processing proceeds to step 205. In step 205, the ECC generated by the ECC circuit 29 is added to each data set as indicated in FIG. 4(C). Further, a preamble 107, address information 109, which includes an address mark, head number, and cylinder number, a postamble 111, and other additional data are added to complete data sector information 113. The resulting data sector information 113 is forwarded to the write channel 21. In step 207, a plurality of pieces of data sector information 113 for the group of data blocks transmitted from the host device 11 are respectively stored in data sectors whose LBAs are specified by the host device 11.

If a CRC error is detected in step 203, the CRC circuit 27 informs the MPU 33 of an error occurrence. The CRC circuit 27 detects a CRC error in the unit of a data set stored in the segment and informs the MPU 33 of a CRC error location by indicating what number data set of a segment is affected by the error. Since the MPU 33 has received the LBA of the leading data set of a segment from the host device 11, it can recognize the LBA of a data sector in which the CRC error occurred and the address of the sector buffer 31 at which the data set has been stored.

In step 209, the buffer controller reads the data set in which the CRC has been detected from segment #1 via the buffer controller 15. The MPU 33 temporarily stores the contents of a data set in which the error has been detected and its LBA, the segment leading LBA, and the contents of a data set in the RAM, and then records them in the system region 48 of the magnetic disk 25. The MPU 33 may directly record the address of the sector buffer 31 at which the data set affected by the CRC error has been stored, instead of the LBA of the data set in which the error has been detected and the LBA of the segment leading data set.

As a result, the address information about the sector buffer 31 in which the data set affected by the CRC error was stored and the data set are recorded in the system region 48 so that the information for analyzing the cause of soft error can be accumulated later. In step 211, the MPU 33 sets an error bit in the status register of the host interface circuit 13 to report an error to the host device 11. The host device 11 references the error bit in the status register, recognizes that an error occurred when a process has been performed to write a previously sent data block group, and transfers the same data block group to the magnetic disk drive 10 again.

In step 213, the magnetic disk drive 10 processes the retransmitted data block group in the same manner as for the previous data block group; however, the MPU 33 uses segment #2, which differs from the first segment (segment #1), as the segment of the sector buffer 31. If a hard error or frequent soft error has occurred in segment #1, a CRC error is detected in a data set group corresponding to the retransmitted data block group so that the performance of the magnetic disk drive 10 degrades. However, the probability of performance degradation can be reduced by using a different segment.

If the magnetic disk drive 10 reports an error a predetermined number of times during a read operation or write operation, the host device 11 generally concludes that the magnetic disk drive 10 is defective. However, handling the magnetic disk drive as a defective drive due to an error that has occurred in one segment is not economically appropriate. Such a situation can be avoided by using a different segment for storage purposes. In step 215, as is the case with step 203, the buffer controller 15 sequentially reads a group of data sets stored in segment #2 of the sector buffer, and the CRC circuit 27 checks for a CRC error in each data set.

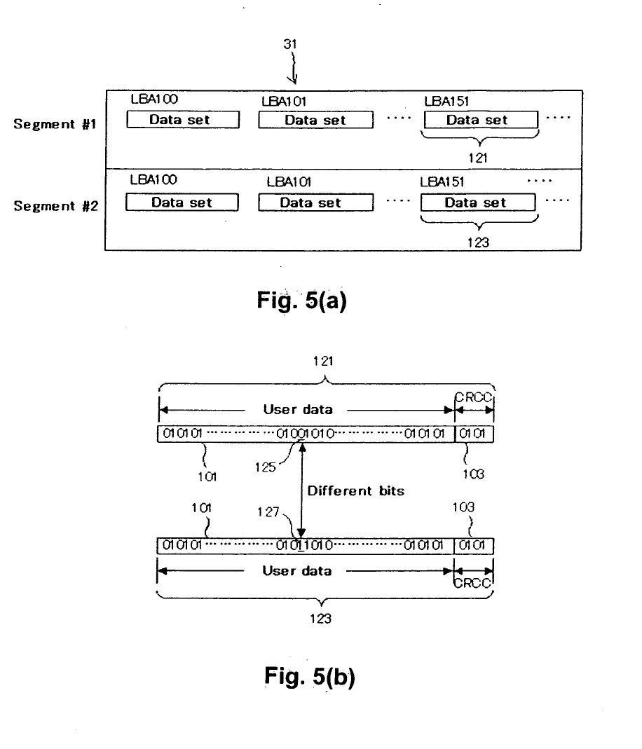

If a CRC error is detected in a data set within the data set group stored in segment #2, processing returns to step 211 so that the same procedure is repeated. If, in step 215, the CRC error is not detected in any data set within the data set group stored in segment #2, processing proceeds to step 217. In step 217, the data set groups in segments #1 and #2 are compared on a bit-by-bit basis. This comparison operation will now be described with reference to FIGS. 5(A) and 5(B). Referring to FIG. 5(A), segments #1 and #2 store groups of 800 data sets (LBA 100 to LBA 899). The data set groups are made of the same user data (data blocks), which are transmitted from the host device 11.

If a CRC error occurs in a data set 121 that corresponds to LBA 151 of segment #1, the CRC circuit 27 cannot identify the inverse bit position. Therefore, the MPU 33 cannot recognize the error bit address of the sector buffer 31 although it recognizes a sector buffer address at which the data set 121 has been stored. In the present embodiment, the user data 101 and CRCCs 103 of the data set groups in segments #1 and #2 are compared on a bit-by-bit basis by using an exclusive OR circuit.

Then, as indicated in FIG. 5(B), it is detected that bit 125 of data set 121 differs from bit 127 of data set 123. In step 215, it has been found that no CRC error occurred in data set 123. It means that bit 125 is inverted while bit 127 is not inverted. The MPU 33 calculates the sector buffer address of bit 125. In step 219, the MPU 33 records in the system region 48 the error bit address and the LBA corresponding to the data set containing the error bit. When the error bit address is recorded in the system region 48, more useful information required for analyzing the cause of sector buffer soft error can be obtained later. Here, the data set groups are compared on an individual segment basis. However, since the LBAs corresponding to the data set in which the CRC error occurred are known, the MPU 33 may simply compare the data sets at the LBAs.

In step 221, segment #1 in which the CRC error occurred is disabled. If an error segment is continuously used, the CRC error may recur, thereby degrading the performance of the magnetic disk drive 10. For optimum performance, it is preferred that the error segment be disabled. Disabling is done on an individual segment basis because sector buffer control is easy. However, if emphasis is placed on the sector buffer capacity, disabling may be done in the unit of a data set storage region, which is composed of 516 bytes. When disabling is to be done on an individual segment basis, the unit of a segment should be reduced to minimize the ratio at which a normal storage region is disabled.

It is often said that soft errors cannot be perfectly avoided. In this instance, a particular address can be disabled only when a soft error occurred at it a multiple number of times. Disabling an error segment occurs in a situation where a CRC error occurred in the same segment a predetermined number of times, a CRC error occurred at the same data set address of the same segment a predetermined number of times, or a CRC error occurred at the same bit address a predetermined number of times.

Further, segment #1 may be disabled only when the data set group of segment #2 is stored in segment #1 again and a CRC error is detected again in the data set group that is stored again in segment #1. If the CRC error recurs in segment #1 in this instance, it is highly probable that a hard error is encountered. Therefore, it is preferred that segment #1 be disabled immediately to prevent subsequent performance degradation.

The result of a CRC error check that is performed on the data set group read from segment #1 after the data set group of segment #2 is stored in segment #1 should be recorded in the system region 48 without regard to the occurrence of a CRC error. It means that a reproduction test is performed with the same data pattern. Therefore, it makes it possible to obtain useful information for analyzing the cause of a pattern-dependent soft error.

Process for a Data Read

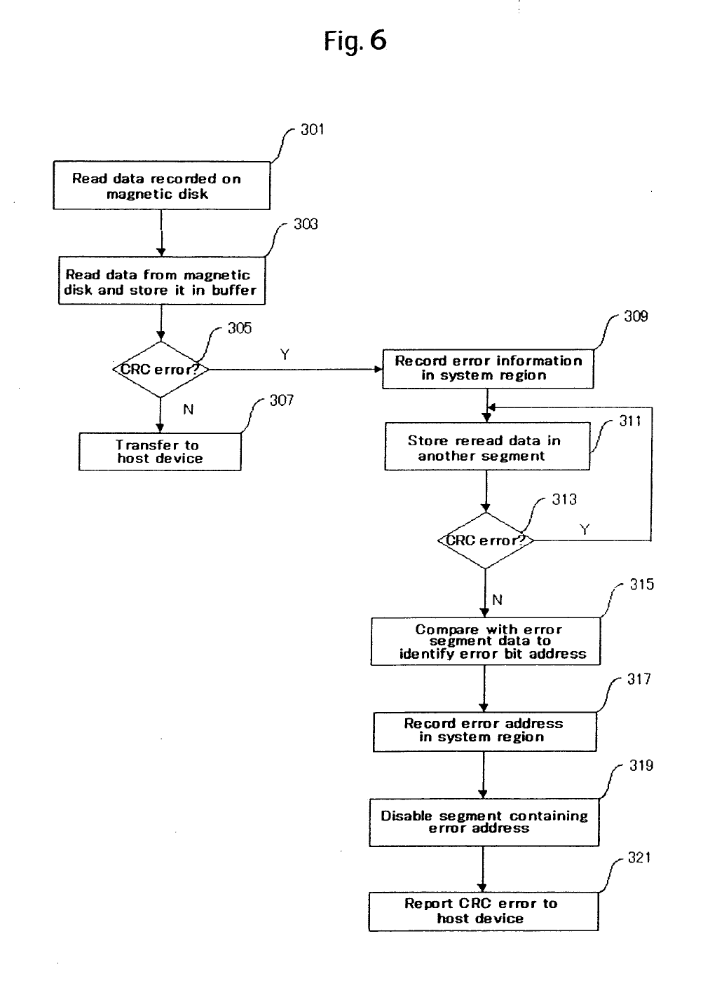

FIG. 6 is a flowchart illustrating a sector buffer management procedure according to the present embodiment that is employed when the host device 11 reads data from the magnetic disk 25. On the magnetic disk 25, the data sector information 113 having the data structure shown in FIG. 4(C) is written in each data sector shown in FIG. 2(B). The host device 11 has the information about the data sector leading LBA and the number of data sectors on an individual file basis.

When, in step 301, the host device 11 specifies the leading data sector LBA of the file to be read from the magnetic disk 25 and the number of data sectors to be read and sends a read command to the magnetic disk drive 10, the magnetic disk drive 10 starts to perform a read process. A read data set 115, which is processed by the read channel 19 and composed of user data, CRCC, and ECC, is sent to the channel interface circuit 17. The ECC circuit 29 uses the ECC 105 to check each read data set 115 for an ECC error in the data set 100, which includes the user data 101 and CRCC 103. If the number of error bits is within the correction capacity, the ECC circuit 29 corrects the data set 100. The corrected data set group is sent from the channel interface circuit 17 to the buffer controller 15.

If the number of ECC error bits in the read data set 115 exceeds the correction capacity of the ECC circuit 29, the steps of an error recovery procedure (ERP) are sequentially performed to achieve error recovery. If it is eventually concluded that error recovery is unachievable, the host device 11 is informed of such an unrecoverable error. Since the data set 100 that includes the user data 101 and CRCC 103 and is sent to the buffer controller 15 has been subjected to error correction, it has the same value as the data set that has been read from the sector buffer 31 at the time of a write. However, the ECC circuit 29 might make erroneous corrections with a very low probability.

In step 303, the buffer controller 15 stores the read data set group in segment #1 of the sector buffer 31 specified by the MPU 33. In step 305, the buffer controller 15 reads the data set group from segment #1 with timing for data transfer to the host device 11, and the CRC circuit 27 checks for a CRC error in each data set. If it is judged that the CRC error has not occurred in any data set within the data set group in segment #1, step 307 is performed to remove the CRC from each data set and send a data block comprising 512 bytes of user data to the host device 11.

If, in step 305, a CRC error is detected in a data set, processing proceeds to step 309. In step 309, the data information and address information concerning the CRC error are recorded in the system region 48 for the same reason and by performing the same procedure as in step 209, which is shown in FIG. 3. In step 311, the MPU 33 reads the read data set 115, which comprises the user data, CRCC, and ECC, from the LBA of the magnetic disk 25 at which the data set group stored again in data segment #1 has been recorded. The buffer controller 15 then stores the reread data set group in segment #2, which differs from the initial storage location (segment #1).

In a situation where a hard error or frequent soft error has occurred in segment #1, the use of another segment of the sector buffer 31 makes it possible to prevent the performance of a read process from degrading due to a CRC error recurrence. In step 315, the data set groups of segments #1 and #2 are compared on a bit-by-bit basis as is the case with step 217, which is shown in FIG. 3. The MPU 33 calculates the address of the sector buffer at which a bit inversion error of segment #1 has occurred. In step 317, the MPU 33 records the address of an error bit and the LBA corresponding to a data set containing the error bit in the system region 48.

In step 319, segment #1 in which the CRC error occurred is disabled as is the case with step 221, which is shown in FIG. 3. The disabling conditions can be predefined as is the case with step 221. In step 321, the MPU 33 sets an error bit in the status register to inform the host device 11 that an error occurred during a read command process.

Use of Error Information

To analyze the failure of the sector buffer used in the magnetic disk drive 10 and provide increased reliability, it is important that the CRC error be reproduced. If a CRC error occurs in a data set stored in the sector buffer during a write operation or read operation, the present embodiment stores the error occurrence time, the contents of the data set, the error bit buffer address or the LBA corresponding to a data set containing an error bit, and the like in the system region 48 of the magnetic disk 25. A magnetic disk drive 10 classified as a faulty drive by the host device 11 due to a frequently encountered CRC error is collected, and the error information in the system region 48 is read by an analysis technician and used for reproduction testing.

To reproduce a CRC error in a situation where an analysis is made to judge whether a soft error depends on a bit pattern, it is particularly necessary to determine the address of the sector buffer and the contents of a data set. The present embodiment records such information in the system region 48. Formerly, data was repeatedly retransferred from the host device at the time of a write or repeatedly reread from the magnetic disk 25 at the time of a read during the time interval between the instant at which a CRC error occurred in the sector buffer 31 and the instant at which the host device 11 concluded that the magnetic disk drive 10 was faulty. However, the present embodiment makes it possible to avoid-a situation where the magnetic disk drive 10 is continuously used while its performance is degraded.

While the present invention has been described in conjunction with a specific embodiment that is illustrated in the accompanying drawings, it is not limited to the embodiment illustrated in the drawings. Persons of skill in the art will appreciate that the present invention can be applied to any known configuration as far as it provides the advantages of the present invention.

What is claimed is:

1. An auxiliary storage device connectable to a host device, comprising:
an error code generation section for generating an error checking code that corresponds to a user data block transferred from the host device;
a nonvolatile recording medium for recording a data set that includes the user data block and the error checking code;
a buffer for storing the data set before a data transfer between the recording medium and the host device;
an error detection section that uses the error checking code to check for an error in the data set stored in the buffer; and
a processor, which, when the error detection section detects an error in a first data set stored in the buffer, records on the recording medium the first data set and an address of the buffer at which the first data set has been stored.

2. The auxiliary storage device according to claim 1, wherein the address of the buffer includes a logical block address (LBA) corresponding to the first data set.

3. The auxiliary storage device according to claim 1, wherein, when the error detection section detects an error in the first data set during a write operation, the same user data block as the user data block constituting the first data set is transferred again from the host device, and a second data set, which includes the user data block transferred again to an address of the buffer that differs from the address at which the first data set has been stored and an error checking code corresponding to the transferred user data block, is stored.

4. The auxiliary storage device according to claim 3, wherein, when the error detection section does not detect an error in the second data set stored in the buffer, the processor compares the first data set and the second data set on a bit-by-bit basis to locate an error bit address concerning the first data set and records the error bit address on the recording medium.

5. The auxiliary storage device according to claim 1, wherein, when the error detection section detects an error in the first data set during a read operation, a data set is read from an address of the recording medium at which the first data set has been recorded, and stored as a second data set at an address of the buffer that differs from the address at which the first data set has been stored.

6. The auxiliary storage device according to claim 5, wherein, when the error detection section does not detect an error in the second data set stored in the buffer, the processor compares the first data set and the second data set on a bit-by-bit basis to locate an error bit address concerning the first data set and records the error bit address on the recording medium.

7. The auxiliary storage device according to claim 1, wherein, when an error is detected in the first data set, the auxiliary storage device reports the detected error to the host device.

8. The auxiliary storage device according to claim 1, wherein the processor records in a system region of the recording medium a data set in which the error has been detected and an address of the buffer at which the data set has been stored.

9. The auxiliary storage device according to claim 1, wherein the error code generation section generates the error checking code by a cyclic redundancy check (CRC) method.

10. An auxiliary storage device connectable to a host device, comprising:
an error code generation section for generating an error checking code that corresponds to a user data block transferred from the host device;
a nonvolatile recording medium for recording a data set that includes the user data block and the error checking code;
a buffer for storing the data set before a data transfer between the recording medium and the host device;
an error detection section that uses the error checking code to check for an error in the data set stored in the buffer; and
a processor, which, when the error detection section detects an error in a first data set stored in the buffer, disables an address of the buffer at which the first data set has been stored.

11. The auxiliary storage device according to claim 10, wherein the recording medium is a magnetic disk; and wherein the error checking code is generated by a cyclic redundancy check (CRC) method.

12. The auxiliary storage device according to claim 10, wherein, when a predetermined number of errors are detected in the first data set stored in the buffer, the processor disables an address of the buffer at which the first data set has been stored.

13. The auxiliary storage device according to claim 10, further comprising:
an error correction code generation section for correcting an error in a data set read from the recording medium.

14. The auxiliary storage device according to claim 10, wherein, when the error detection section detects an error in the first data set during a write operation, a second data set, which includes a user data block constituting the first data set transferred again from the host device and an error checking code corresponding to the user data block, is stored at an address of the buffer at which the first data set has been stored; and wherein, when the error detection section detects an error in the second data set stored in the buffer, the processor disables an address of the buffer at which the first data set has been stored.

15. The auxiliary storage device according to claim 10, wherein, when the error detection section detects an error in the first data set during a read operation, the data set read again from the same address as the address of the first data set on the magnetic disk is stored, as a second data set, at an address of the buffer at which the first data set has been stored; and wherein, when the error detection section detects an error in the second data set stored in the buffer, the processor disables an address of the buffer at which the first data set has been stored.

16. A read/write method for reading/writing data in a magnetic disk drive including a buffer for storing data transferred between a magnetic disk and a host device, the read/write method comprising the steps of:
calculating a redundant byte corresponding to a user data block transferred from the host device by a cyclic redundancy check (CRC) method, and generating a data set that includes the user data block and the redundant byte;
storing the data set in the buffer;
checking for a CRC error in the data set stored in the buffer by using the redundant byte; and
disabling an address of the buffer at which a data set whose CRC error has been detected has been stored.

17. The read/write method according to claim 16, further comprising the steps of:
reporting to the host device the address of the buffer at which the CRC error has been detected; and
causing the host device to disable the reported address of the buffer.

18. The read/write method according to claim 16, further comprising the step of:
storing in a system region of the magnetic disk a data set whose CRC error has been detected and an address of the buffer at which the data set has been stored.

19. The read/write method according to claim 16, further comprising the step of:
storing in a system region of the magnetic disk a data set whose CRC error has been detected and an error bit address of the buffer at which the data set has been stored.

20. The read/write method according to claim 16, wherein the buffer is divided into a plurality of segments; and wherein the step of disabling an address of the buffer includes a step of disabling an address of the buffer on an individual segment basis.
